(19) United States
(12) Patent Application Publication
(10) Pub. No.: US 2025/0309896 A1
(43) Pub. Date: Oct. 2, 2025

(54) High Pull-up Slew Rate and Low Quiescent Power for Gate Driver and Logic Elements

(71) Applicant: Finwave Semiconductor, Inc., Belmont, MA (US)

(72) Inventors: Shylesh Srinivasan, Brighton, MA (US); Dongfei Pei, Waban, MA (US); Bin Lu, Fremont, CA (US)

(21) Appl. No.: 19/079,669

(22) Filed: Mar. 14, 2025

Related U.S. Application Data
(60) Provisional application No. 63/569,991, filed on Mar. 26, 2024.

(51) Int. Cl. H03K 19/017

(52) U.S. Cl. CPC H03K 19/01714; H03K 19/01721

(57) ABSTRACT

A new inverting logic gate or a FET gate driver is disclosed. The logic gate mitigates the trade-off between power dissipation (or quiescent power) and slew rate of the typical RTL and DLL buffers by using an innovative circuit topology involving a pull-up bootstrapping transistor. The bootstrapping transistor may be an enhancement mode GaN field effect transistor (FET). This bootstrapping transistor may be driven by the complement of the input signal. Alternatively, the bootstrapping transistor may monitor the drain terminal of the pull-down transistor and conduct current accordingly. Other Boolean functions may also be achieved using this approach.

This application claims priority to U.S. Provisional Patent Application Ser. No. 63/569,991, filed Mar. 26, 2024, the disclosure of which is incorporated herein by reference in its entirety.

### FIELD

Embodiments of the present disclosure relate to a semiconductor structure and methods for making a semiconductor structure with a faster pull-up slew rates and low quiescent power.

### BACKGROUND

The superiority of Gallium Nitride (GaN) High Electron Mobility Transistors (HEMT) over Silicon (Si) transistors is well known. The key attractive features of GaN HEMT are its capability to operate at higher frequency, voltage, power density and efficiency which are attributable to its higher electron mobility and larger band-gap than silicon. These advantages make GaN semiconductor devices increasingly preferable over silicon devices for applications in Radio Frequency (RF), high voltage and power electronics.

The semiconductor industry and academia are familiar with the disadvantages of GaN HEMT as well. Specifically, GaN based N-channel FETs have successfully transitioned to commercially viable products with an increasing rate of industry wide adoption. This makes GaN technology of high industrial and academic interest. However, one of the disadvantages currently impeding its wider application and market share in modern analog, digital, mixed signal, RF and power electronics is the challenge of making GaN-based high-performance P-channel Field Effect Transistor (FET). To date, P-channel GaN FETs are not commercially viable.

The absence of viable GaN p-channel FETs has been constraining a broad spectrum of applications of GaN FETs because modern electronic circuits often require push-pull power or signal amplification stages that typically include PMOS FETs at the high voltage side and NMOS FETs at the low-voltage side of the circuit's power supply rail. For designing an inverting or a non-inverting buffer or a MOSFET gate driver using GaN FETs, the two (but not necessarily exclusive) viable types of circuit topologies or logic families that do not utilize PMOS FETs are Resistor-Transistor Logic (RTL) and Depletion-Load Logic (DLL). Typical RTL buffer circuits employ a passive element like a resistor to pull-up the buffer's output terminal voltage level to the high-voltage (V_{dd}) side of the power rail. Typical DLL buffer circuits employ an active element, such as a depletion-mode (D-mode) FET configured as a current source to pull-up the output voltage to V_{dd}. The D-mode FET is normally on (or conductive) between its source and drain terminals, unless a negative voltage less than the pinch-off voltage (Vₜₕ) is applied to its gate terminal relative to its source. If the gate terminal is connected to the source, the D-mode FET functions as a constant current source as it operates in its saturation region. Both RTL and DLL buffer circuit implementations use an active element, such as an enhancement-mode (E-mode) FET to pull-down the buffer's output voltage level to the low-voltage (Vₛₛ) side of the power rail. The E-mode FET is normally off (or non-conductive) between its source and drain terminals, until a positive voltage greater than its threshold voltage (Vₜₕ) is applied to the gate terminal relative to its source.

It is important to note that the pull-up element, whether it is the resistor in RTL buffer and the D-mode FET in the DLL buffer circuit, always remains active (or conductive). It is only the pull-down element which can be switched on or off by an external input. Unfortunately, this causes RTL and DLL circuits to consume high static (or quiescent) power, resulting in significant power dissipation across the pull-up elements of the circuit when the pull-down E-mode FET shunts the buffer's output to Vₛₛ. To reduce quiescent power dissipation, if the pull-up element is designed to have a higher impedance, the pull-up and pull-down slew rates become asymmetrical for a given load driven by the buffer, such as the gate terminal of a large power FET or multiple small signal FETs. The gate terminal of the driven FET may be practically characterized as a series Resistor-Capacitor (RC) load. If the impedance of the buffer's pull-up element is higher than that of the pull-down element, the capacitance of the RC load charges and discharges at different rates. In other words, the sourcing power of the buffer is lower than its sinking power, resulting in slower pull-up slew rate than the pull-down slew rate of the output signal.

Therefore, it would be beneficial if there was a system to increase the pull-up slew rate to make it roughly equal in magnitude to the pull-down slew rate, while maintaining a low quiescent current.

### SUMMARY

A new inverting logic gate or FET gate driver for Gallium Nitride (GaN) based processes is disclosed. The logic gate or FET gate driver mitigates the trade-off between power dissipation (or quiescent power) and slew rate of the typical RTL and DLL buffers by using an innovative circuit topology involving a pull-up bootstrapping transistor. The bootstrapping transistor may be an enhancement mode GaN field effect transistor (FET). This bootstrapping FET may be driven by the complement of the input signal. Alternatively, the bootstrapping transistor may be driven by a circuit which monitors the voltage at the drain terminal of the pull-down FET and triggers the bootstrapping FET to conduct current accordingly. In addition to an inverting logic gate, other Boolean functions may also be achieved using this approach.

According to one embodiment, a logic gate or a FET gate driver is disclosed. The logic gate or a FET gate driver comprises an input signal, in electrical connection with a pull-down element, wherein the pull-down element is in electrical communication with an output signal and ground; an inverting buffer in electrical connection with the input signal to generate an intermediate output; a bootstrapping field effect transistor (FET), wherein a gate of the bootstrapping FET is electrically connected to the intermediate output, a source of the bootstrapping FET is electrically connected to the output signal, and a drain of the bootstrapping FET is electrically connected to a power rail; and a pull-up element in parallel with the bootstrapping FET, to continuously supply current from the power rail to the output signal. In some embodiments, the pull-down element comprises an enhancement mode FET having a gate electrically connected to the input signal, a source electrically connected to ground and a drain electrically connected to the output signal. In some embodiments, the pull-up element comprises a resistor. In some embodiments, the pull-up element comprises a depletion mode FET, wherein a source and a gate of the depletion mode FET are connected to the output signal. In some embodiments, the bootstrapping FET comprises an enhancement mode FET. In some embodiments, the logic gate or the FET gate driver is made using GaN.

According to another embodiment, a logic gate is disclosed. The logic gate comprises one or more input signals, each electrically connected to a pull-down logic circuit, wherein the pull-down logic circuit is electrically connected to an output signal and ground; a non-inverting driver electrically connected to the output signal to generate an intermediate output; a bootstrapping field effect transistor (FET), wherein a gate of the bootstrapping FET is electrically connected to the intermediate output, a source of the bootstrapping FET is electrically connected to the output signal, and a drain of the bootstrapping FET is electrically connected to a power rail; and a pull-up element in parallel with the bootstrapping FET, to continuously supply current from the power rail to the output signal. In some embodiments, the pull-up element comprises a resistor. In some embodiments, the pull-up element comprises a depletion mode FET, wherein a source and a gate of the depletion mode FET are connected to the output signal. In some embodiments, the pull-down logic circuit comprises one or more enhancement mode FETs, each having a gate electrically connected to a respective one of the one or more input signals. In certain embodiments, the one or more enhancement mode FETs are arranged in series and/or parallel. In some embodiments, the one or more input signals comprise one input signal, and wherein the pull-down logic circuit comprises one enhancement mode FET with a gate electrically connected to the one input signal, a source connected to ground and a drain connected to the output signal. In some embodiments, the non-inverting driver comprises a comparator, having a positive input electrically connected to the output signal, a negative input electrically connected to a threshold voltage, and wherein an output of the comparator is the intermediate output. In certain embodiments, the threshold voltage is generated using a reference current source and a resistor. In some embodiments, the logic gate is made using GaN.

### BRIEF DESCRIPTION OF THE FIGURES

For a better understanding of the present disclosure, reference is made to the accompanying drawings, which are incorporated herein by reference and in which:

FIG. 1 is a generalized topology of an improved inverting buffer design according to one embodiment;

FIG. 2 is a specific topology of the improved inverting buffer design of FIG. 1;

FIG. 3 shows a topology of an improved inverting buffer according to another embodiment;

FIG. 4 shows a generalized topology of an improved logic gate according to one embodiment;

FIG. 5 shows a specific topology of the improved logic gate of FIG. 4;

FIG. 6 shows the topology of the non-inverting driver according to one embodiment; and

FIGS. 7A-7B show the difference in the rise time of the output signal between a traditional inverting buffer and the inverting buffer of FIG. 3.

### DETAILED DESCRIPTION

This disclosure describes an inverting logic gate and a FET gate driver with improved pull-up slew rate and low quiescent power. A logic gate is an electrical circuit that receives one or more inputs and using logic, generates one or more outputs.

This description is presented primarily in the context of circuit design at the Integrated Circuit (IC) level, which includes Application Specific IC (ASIC), Large Scale Integration (LSI), Very Large Scale Integration (VLSI), System on Chip (SoC) and other forms of integration on a single die or chip. However, the ideas disclosed herein may be scaled to serve identical and various other purposes in circuit design at the 2D and 3D chip or package involving heterogeneous integration of multiple dies, at the module level involving the integration of multiple packages or dies, at the PCB level, or at any level of design integration hierarchy.

In all of the embodiments described herein, the quiescent power of a typical RTL or DLL based inverting (or a non-inverting) buffer may be minimized by maintaining the impedance of the pull-up element high during the output's static states, and temporarily reduced only during the output's transition from a low to high state to increase the slew rate.

In all of the embodiments, this is achieved by the use of a traditional pull-up element, such as a resistor or depletion mode FET, and a bootstrapping enhancement mode FET, which is arranged in parallel.

Unlike the traditional pull-up element, which is always conducting current, the bootstrapping FET is only active for a brief time during the transition of the output of the logic gate from a low state to a high state.

In this disclosure, the term “pull-up slew rate” denotes the rate at which the output signal transitions from a low voltage to a high voltage. The pull-up slew rate is determined by the elements that are located between the power rail and the output signal, and the load impedance attached to the output signal. The term “pull-down slew rate” denotes the rate at which the output signal transitions from a high voltage to a low voltage. The pull-down slew rate is determined by the pull-down elements that are located between ground and the output signal, and the load impedance attached to the output signal.

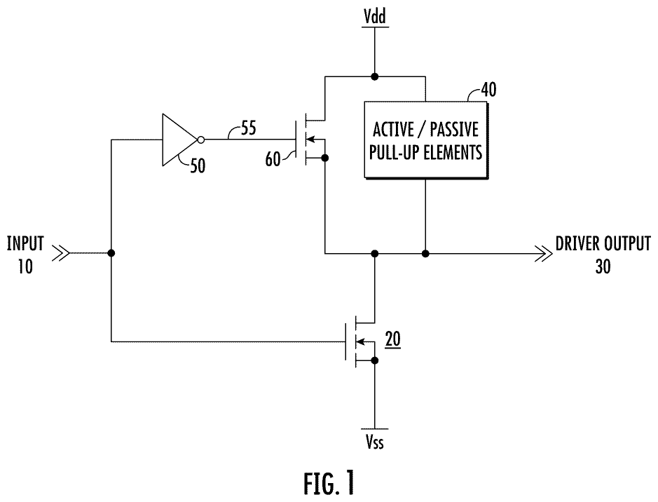

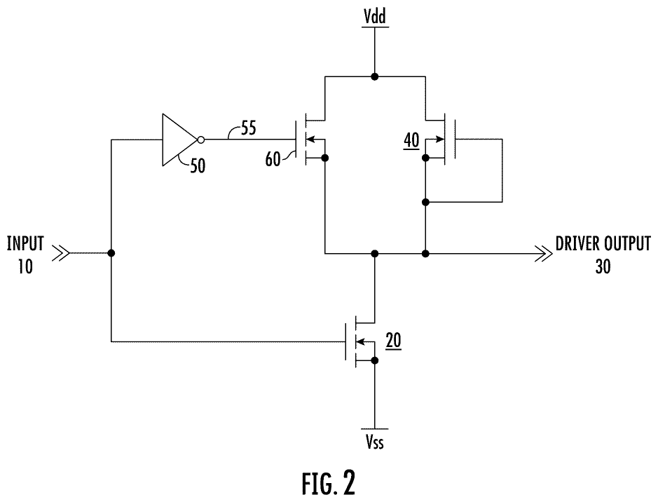

FIG. 1 shows a first embodiment, which represents a generalized topology. The logic gate includes an input signal 10, which may comprise two distinct states, a low voltage and a high voltage. This input signal 10 serves as an input to the gate of a pull-down element 20, which is typically an enhancement mode FET. The source of the pull-down element 20 is connected to ground, also referred to as Vₛₛ, while the drain of the pull-down element 20 serves as the output signal 30 of the logic gate. A pull-up element 40 is disposed between the power rail (also referred to as V_{dd}) and the output signal 30. This pull-up element 40 conducts current from the power rail to the output signal 30 continuously. In one embodiment, the pull-up element 40 may be resistor. In another embodiment, shown in FIG. 2, the pull-up element 40 may be a depletion mode FET, where the source of the depletion mode FET is connected to the gate of the depletion mode FET to ensure that the depletion mode FET is always in saturation mode.

In addition, an inverting buffer 50 also receives the input signal 10 and inverts that input to produce an intermediate output 55. Thus, when the input signal 10 is at a low voltage, the intermediate output 55 is at a high voltage and when the input signal 10 is at a high voltage, the intermediate output 55 is at a low voltage. The inverting buffer 50 may be a traditional inverting buffer, which includes a pull-down element (such as an enhancement mode FET) and a pull-up element (such as a resistor or a depletion mode FET). The intermediate output 55 serves as the input to the gate of the bootstrapping FET 60. The bootstrapping FET 60 may be an enhancement mode FET, with its drain electrically connected to the power rail, V_{dd}, and its source connected to the output signal 30.

In operation, the bootstrapping FET 60 serves to increase the pull-up slew rate by providing a low impedance path to the pull-up source current. Assume that the input signal 10 is at a high voltage. In this case, the pull-down element 20 is conducting and the output signal 30 is at a low voltage, nearly equal to Vss, which may be electrical ground. The pull-up element 40 is always conducting, and the current produced by the pull-up element 40 is sunk by the pull-down element 20. The bootstrapping FET 60 is disabled at this time. When the input signal 10 transitions from a high voltage to a low voltage, the pull-down element 20 is disabled and no longer conducts. Additionally, the inverting buffer 50 produces a high voltage at the intermediate output 55. The output signal 30 is pulled up toward the power rail by the pull-up element 40. The output signal 30 is typically also connected to the gates of one or more downstream transistors, which act as capacitive elements. Thus, the voltage of the output signal 30 increases according to an RC constant that is determined by the load on the output signal 30 and the current produced by the pull-up element 40. Thus, when the input signal 10 first transitions, there is a positive voltage difference between the gate of the bootstrapping FET 60 and its drain (which is tied to the output signal 30). Thus, the bootstrapping FET 60 is also enabled and also supplies current to the output signal 30. However, as the voltage of the output signal 30 continues to increase, the voltage between the gate and the drain of the bootstrapping FET 60 drops below the threshold voltage of the bootstrapping FET 60, and the bootstrapping FET 60 becomes disabled. The pull-up element 40 continues to provide current to the output signal 30, but the bootstrapping FET 60 is now disabled. The transition of the input signal 10 from a low voltage to a high voltage enables the pull-down element 20 to conduct, driving the output signal 30 to a low voltage. The bootstrapping FET 60 remains disabled, as the intermediate output 55 is now at a low voltage.

Therefore, in summary, when the bootstrapping FET 60 becomes conductive, it provides a low impedance path for the pull-up current sourced from V_{dd} to the output signal 30. Thus, the improved inverting buffer design offers higher pull-up power for driving its load from a low state to high state. This facilitates a quicker pull-up slew rate of the output signal 30, as compared to the typical inverting buffer circuit without the bootstrapping FET 60.

While FIGS. 1-2 show that the logic gate is an inverter, this configuration may be used for other logic functions, especially those that are required to have a large fan-out when integrated into high-speed logic blocks. For example, a logic NAND gate may be created by having the pull-down elements 20 for each input in series. The bootstrapping FETs 60 may be arranged in parallel with each other and with the pull-up element 40. Additionally, this concept may be used for FET gate drivers, which are electrical circuits that receive a low power input and generate a large amount of current that can be used to switch the attached FET quickly. This is useful when the gate of the attached FET has a large capacitance.

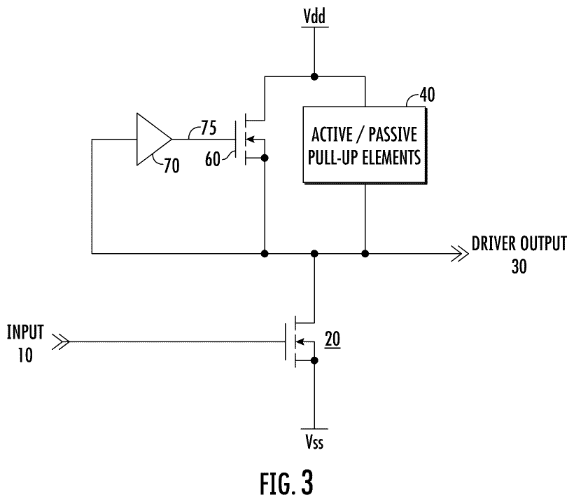

Another embodiment is shown in FIG. 3. In this embodiment, the gate of the bootstrapping FET 60 is driven by a non-inverting driver 70 based on the feedback of the output signal 30. In this topology, the non-inverting driver 70 may incorporate voltage level shifting circuitry depending on the design requirements of the logic gate. This embodiment with the bootstrapping FET 60 driven by the feedback of the output signal 30 may avoid a potential short-circuit between the V_{dd} and Vₛₛ power rails, by preventing concurrent conduction of pull-down element 20 and bootstrapping FET 60. When the input of non-inverting driver 70 is fed with the output signal 30, it ensures that the bootstrapping FET 60 is triggered to conduct only after the pull-down element 20 has been completely turned off.

In operation, the bootstrapping FET 60 assists in supplying current during the transition of the input signal 10 from high to low. Specifically, assume that the input signal is at a high voltage. In this scenario, the pull-down element 20, which may be an enhancement mode FET, is enabled and sinks current from the output signal 30. The pull-up elements 40 are as described above, and continuously supply current from the power rail to the output signal 30. When the input signal 10 falls from a high voltage to low, the pull-down element 20 turns off and the pull-up element 40 causes the voltage level of the output signal 30 to start to rise towards V_{dd}. At this time, the intermediate output 75 from the non-inverting driver 70 is also at a low voltage, and the bootstrapping FET 60 is disabled. When the voltage level of the output signal 30 rises beyond the turn-on threshold of the non-inverting driver 70, the intermediate output 75 transitions to a high voltage, thereby triggering the bootstrapping FET 60 to conduct. As the voltage of the output signal 30 continues to rise, eventually, it reaches a voltage such that the difference between the gate and source of the bootstrapping FET 60 is less than its threshold voltage, thereby disabling the bootstrapping FET 60. Thus, the bootstrapping 60 is only enabled for a portion of the transition of the output signal 30.

Thus, the possibility of the bootstrapping FET 60 turning on to boost the pull-up while the pull-down element 20 concurrently pulls down the output signal 30 is practically eliminated, avoiding Vdd-Vss rail short circuit losses. This self-governed pull-up boosting is critical to ensure the device's superior output performance and power low consumption in its static and transitional states.

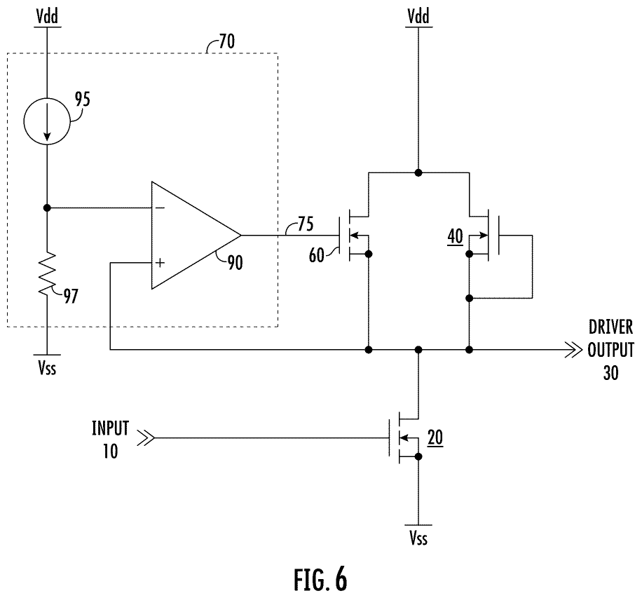

The non-inverting driver 70 may be formed in a plurality of ways. The design of non-inverting driver 70 may be tailored to meet specific slew rates of the rising edge at output signal 30 while ensuring that the bootstrapping FET 60 and pull-down element 20 are not concurrently turned on. In one embodiment as shown in FIG. 6, the non-inverting driver 70 may be designed to serve as a low threshold voltage trigger for bootstrapping FET 60. In this embodiment, a comparator 90 is used. The output of the comparator 90 is the intermediate output 75, described above. The positive input to the comparator 90 is electrically connected to the output signal 30, while the negative input is electrically connected to a threshold voltage. In this embodiment, the threshold voltage is generated using a reference current source 95 to provide a constant current through a resistor 97. The threshold voltage is defined as the input voltage at which the comparator 90 transitions the intermediate output 75 to the high voltage level. The reference current source 95 may be tuned to set a low turn-on voltage for bootstrapping FET 60 to drive the load connected at the output signal 30 sooner and assist in reducing the rise-time. Of course, the non-inverting driver 70 may be configured in other ways as well.

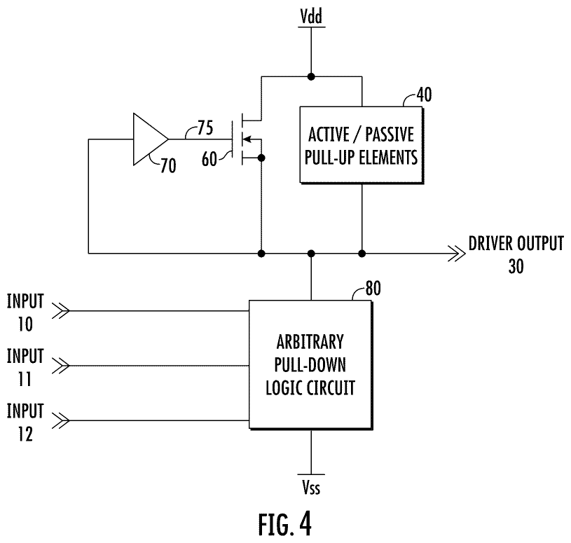

A generalized topology of a logic gate that uses the non-inverting driver 70 of FIG. 3 is shown in FIG. 4. This logic gate implements an arbitrary pull-down logic circuit 80 with an arbitrary number of inputs. For example, in FIG. 4, there are three inputs, input signal 10, input signal 11 and input signal 12 to the arbitrary pull-down logic circuit 80. These three input signals may be combined in any desired combination. The arbitrary pull-down logic circuit 80 may be made up of a plurality of enhancement mode FETs arranged in series and/or parallel. The remainder of the logic gate is as described above, wherein there is a pull-up element 40 that supplies a continuous current to the output signal 30. Additionally, the non-inverting driver 70 and bootstrapping FET 60 are as described with respect to FIG. 3. Thus, as described above, when the arbitrary pull-down logic circuit is not sinking current, the voltage of the output signal 30 begins to rise. At some voltage, the non-inverting driver 70 is triggered and drives the intermediate output 75 to a high voltage, thereby enabling the bootstrapping FET 60. When the voltage of the output signal 30 become sufficiently high, the bootstrapping FET 60 is disabled.

Comparing FIGS. 3 and 4, it can be seen that FIG. 3 is a specialized version of FIG. 4, wherein the arbitrary pull-down logic circuit 80 comprises a single enhancement mode FET with a single input signal connected to its gate.

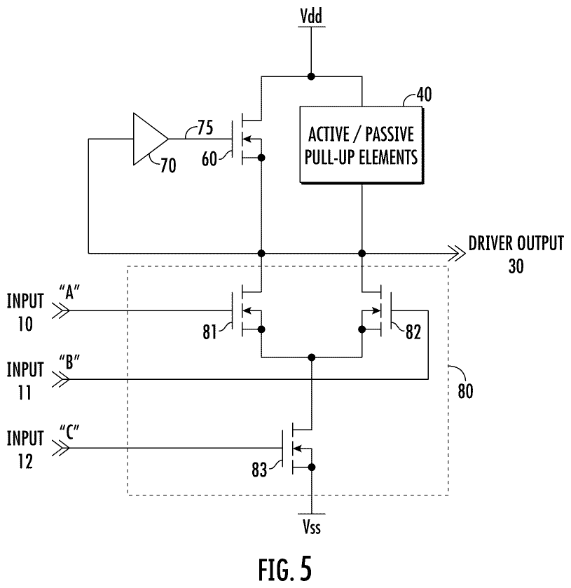

A more complicated arbitrary pull-down logic circuit 80 is shown in FIG. 5. In this figure, the three input signals, which are also denoted as A, B, and C are combined to form the Boolean function:

$$\overline{( A + B ) * C}$$

wherein “+” indicates a logical OR and “*” indicates a logical AND. The line over the Boolean function indicates that the output is the complement of this function. Thus, when at least one of A or B is at a high voltage and C is also at a high voltage, the output signal 30 will be pulled to the low voltage. This Boolean function is achieved using enhancement mode transistors. The gate of each enhancement mode FET is connected to a respective input signal. The enhancement mode FET 81 and enhancement mode FET 82 are arranged in parallel, wherein their drains are both connected to the output signal 30 and their sources are also connected together and connected to the drain of the enhancement mode FET 83. The source of the enhancement mode FET 83 is connected to ground. Note that the use of the non-inverting driver 70 and bootstrapping FET 60 operates correctly regardless of the Boolean function that is implemented by the arbitrary pull-down logic circuit 80.

These structures have many advantages. With respect to FIGS. 1-2, the pull-up and pull-down slew rate are more symmetric as compared to that of the typical inverting buffer design. The higher pull-up slew rate and its symmetricity to the pull-down slew rate make the improved inverting buffer design superior in performance and suitable for high-speed gate driving applications and signal buffering. In this steady high state, the inverting buffer consumes less power as it needs to only provide for the minor leakage current of the RC load. Thus, its pull-up element 40 is tuned to satisfy this low steady-state output power requirement. When the input signal 10 receives a high-level voltage and turns on pull-down element 20 to pull-down the output voltage level to Vₛₛ, the impedance of the pull-up element 40 is still high enough to dissipate less power as compared to the typical DLL based or RTL based inverting buffer design. This way, the quiescent power of the augmented DLL (or RTL) inverting buffer during its output's steady high state and low state is much lower than the typical inverting buffer.

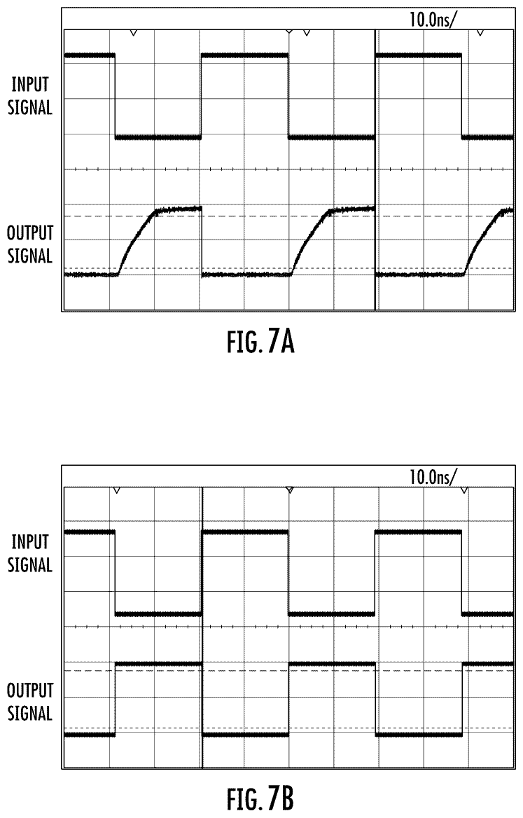

With respect to FIGS. 3-5, a key advantage of using the inverting buffer in conjunction with the bootstrapping FET in logical elements or blocks is the ability to increase the fan-out while maintaining high speed operation and low quiescent power. This enables complex logic circuits using this design to consume less power than if made up of typical DLL or RTL NMOS logic. FIGS. 7A-7B show the benefits of the bootstrapping FET. FIG. 7A shows the input signal 10 and the resulting output signal when the bootstrapping FET is not used and only the pull-up elements 40 are present. In this example, the pull-up element is a depletion mode FET, as is common with traditional inverting buffers. Note that the rise time of the output signal (from 10% to 90%) is roughly 8 ns. FIG. 7B shows the operation of the inverting buffer of FIG. 3, which utilizes the bootstrapping FET 60. Note that the rise time of the output signal (from 10% to 90%) is now about 1 ns. This improvement is especially apparent when the output signal is used to drive a large number of inputs.

Note that in certain embodiments, the FETs described herein are all made using III-nitride technology, such as GaN. However, other technologies may also make use of this structure.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A logic gate or a FET gate driver, comprising:
an input signal, in electrical connection with a pull-down element, wherein the pull-down element is in electrical communication with an output signal and ground;
an inverting buffer in electrical connection with the input signal to generate an intermediate output;
a bootstrapping field effect transistor (FET), wherein a gate of the bootstrapping FET is electrically connected to the intermediate output, a source of the bootstrapping FET is electrically connected to the output signal, and a drain of the bootstrapping FET is electrically connected to a power rail; and
a pull-up element in parallel with the bootstrapping FET, to continuously supply current from the power rail to the output signal.

2. The logic gate or the FET gate driver of claim 1, wherein the pull-down element comprises an enhancement mode FET having a gate electrically connected to the input signal, a source electrically connected to ground and a drain electrically connected to the output signal.

3. The logic gate or the FET gate driver of claim 1, wherein the pull-up element comprises a resistor.

4. The logic gate or the FET gate driver of claim 1, wherein the pull-up element comprises a depletion mode FET, wherein a source and a gate of the depletion mode FET are connected to the output signal.

5. The logic gate or the FET gate driver of claim 1, wherein the bootstrapping FET comprises an enhancement mode FET.

6. The logic gate or the FET gate driver of claim 1, wherein the logic gate or the FET gate driver is made using GaN.

7. A logic gate, comprising:
one or more input signals, each electrically connected to a pull-down logic circuit, wherein the pull-down logic circuit is electrically connected to an output signal and ground;
a non-inverting driver electrically connected to the output signal to generate an intermediate output;
a bootstrapping field effect transistor (FET), wherein a gate of the bootstrapping FET is electrically connected to the intermediate output, a source of the bootstrapping FET is electrically connected to the output signal, and a drain of the bootstrapping FET is electrically connected to a power rail; and
a pull-up element in parallel with the bootstrapping FET, to continuously supply current from the power rail to the output signal.

8. The logic gate of claim 7, wherein the pull-up element comprises a resistor.

9. The logic gate of claim 7, wherein the pull-up element comprises a depletion mode FET, wherein a source and a gate of the depletion mode FET are connected to the output signal.

10. The logic gate of claim 7, wherein the pull-down logic circuit comprises one or more enhancement mode FETs, each having a gate electrically connected to a respective one of the one or more input signals.

11. The logic gate of claim 10, wherein the one or more enhancement mode FETs are arranged in series and/or parallel.

12. The logic gate of claim 7, wherein the one or more input signals comprise one input signal, and wherein the pull-down logic circuit comprises one enhancement mode FET with a gate electrically connected to the one input signal, a source connected to ground and a drain connected to the output signal.

13. The logic gate of claim 7, wherein the non-inverting driver comprises:
a comparator, having a positive input electrically connected to the output signal, a negative input electrically connected to a threshold voltage, and wherein an output of the comparator is the intermediate output.

14. The logic gate of claim 13, wherein the threshold voltage is generated using a reference current source and a resistor.

15. The logic gate of claim 7, wherein the logic gate is made using GaN.
